(19) United States
(12) Patent Application Publication
(10) Pub. No.: US 2024/0243206 A1
(43) Pub. Date: Jul. 18, 2024

(54) Oxide Semiconductor Layer, Thin Film Transistor and Manufacturing Method Therefor, Display Panel, and Display Device

(71) Applicant: BOE TECHNOLOGY GROUP CO., LTD., Chaoyang District, Beijing (CN)

(72) Inventors: Guangcai Yuan, Beijing (CN); Lingyan Liang, Beijing (CN); Hongtao Cao, Beijing (CN); Fengjuan Liu, Beijing (CN); Ce Ning, Beijing (CN); Fei Wang, Beijing (CN); Hehe Hu, Beijing (CN); Xiaolong Wang, Beijing (CN)

(21) Appl. No.: 18/686,604

(22) PCT Filed: Aug. 27, 2021
(86) PCT No.: PCT/CN2021/115155

§ 371 Date: Feb. 26, 2024

(51) Int. Cl. H01L 29/786; H01L 27/12; H01L 29/04; H01L 29/66

(52) U.S. Cl. CPC H01L 29/7869; H01L 27/1222; H01L 29/04; H01L 29/66742

(57) ABSTRACT

A thin film transistor; includes a substrate; and a semiconductor layer provided on the substrate. The semiconductor layer includes a first surface proximate to the substrate and a second surface away from the substrate, and the semiconductor layer is made of a metal oxide semiconductor material. The semiconductor layer has a channel region; and crystals of metal oxide semiconductor are formed at least in the channel region of the semiconductor layer and proximate to the first surface or the second surface.

### CROSS-REFERENCE TO RELATED APPLICATION

This application is the United States national phase of International Patent Application No. PCT/CN2021/115155, filed Aug. 27, 2021, the disclosure of which is hereby incorporated by reference in its entirety.

### BACKGROUND OF THE INVENTION

### Field of the Invention

The present disclosure relates to the field of semiconductor technologies, and in particular, to an oxide semiconductor layer, a thin film transistor and a manufacturing method therefor, a display panel and a display device.

### Description of Related Art

Thin film transistors (TFT) are semiconductor devices usually used in flat panel displays. As pixel control and driving devices in flat panel displays, the TFTs affect the development of flat panel displays.

### SUMMARY OF THE INVENTION

In an aspect, a thin film transistor is provided. The thin film transistor includes a substrate and a semiconductor layer disposed on the substrate. The semiconductor layer includes a first surface proximate to the substrate and a second surface away from the substrate, and a material of the semiconductor layer is a metal oxide semiconductor material. The semiconductor layer has a channel region, and the semiconductor layer is provided with crystals of metal oxide semiconductor at least in the channel region and proximate to one of the first surface and the second surface.

In some embodiments, a thickness of the crystals in the semiconductor layer is greater than or equal to ¼ of a thickness of the semiconductor layer and less than or equal to the thickness of the semiconductor layer.

In some embodiments, a dimension of a distribution range of the crystals in a direction of a length of a channel of the semiconductor layer is greater than or equal to ½ of the length of the channel of the semiconductor layer and is less than or equal to the length of the channel of the semiconductor layer.

In some embodiments, the thin film transistor further includes a metal oxide layer. The metal oxide layer covers at least a middle of the channel region in a direction of a length of a channel, and a dimension of the metal oxide layer in the direction of the length of the channel is greater than or equal to ½ of the length of the channel; and the metal oxide layer is in contact with the semiconductor layer.

In some embodiments, the thin film transistor further includes a gate insulating layer, and the metal oxide layer is disposed between the gate insulating layer and the semiconductor layer.

In some embodiments, in the semiconductor layer, a distribution density of the crystals increases in a direction approaching the metal oxide layer.

In some embodiments, the material of the semiconductor layer is selected from any of indium zinc tin oxide and indium gallium zinc oxide; and the indium zinc tin oxide and the indium gallium zinc oxide are doped or not doped with rare earth elements.

In some embodiments, in a case where the indium zinc tin oxide and the indium gallium zinc oxide are doped with a rare earth element, the rare earth element is praseodymium (Pr) or terbium (Tb).

In some embodiments, in a case where the indium zinc tin oxide is selected as the material of the semiconductor layer, a ratio of a number of atoms of indium (In), a number of atoms of tin (Sn) and a number of atoms of zinc (Zn) in the indium zinc tin oxide is 4:2:4, or a ratio of the number of atoms of In, the number of atoms of Sn and the number of atoms of Zn in the indium zinc tin oxide is 2:4:4. In a case where the indium gallium zinc oxide is selected as the material of the semiconductor layer, a ratio of a number of atoms of In, a number of atoms of gallium (Ga) and a number of atoms of Zn in the indium gallium zinc oxide is 1:1:1.

In some embodiments, a doping concentration of the rare earth element is 2 at %.

In some embodiments, an oxygen vacancy concentration of the semiconductor layer is less than or equal to 10%.

In another aspect, a display panel is provided. The display panel includes the thin film transistor as described above.

In another aspect, a display device is provided. The display device includes the display panel as described above.

In yet another aspect, a manufacturing method for a thin film transistor is provided. The thin film transistor includes a substrate and a semiconductor layer, and the semiconductor layer has a channel region. The manufacturing method includes following steps. A first material layer and a second material layer that are stacked is formed on the substrate, the first material layer is in contact with the second material layer. The first material layer is a whole layer or the first material layer has a same pattern with the semiconductor layer. An orthographic projection of the second material layer on the substrate at least covers a middle of the first material layer corresponding to the channel region in a direction of a length of a channel, and a dimension of the orthographic projection of the second material layer on the substrate in the direction of the length of the channel is greater than or equal to ½ of the length of the channel. A material of the first material layer is a metal oxide semiconductor material, and a material of the second material layer is a metal or a metal oxide.

The first material layer and the second material layer are heated to cause the second material layer to induce the first material layer to form crystals of metal oxide semiconductor at least on a surface proximate to the second material layer at a preset temperature, the preset temperature is greater than or equal to 200° C. and less than or equal to 420° C.

In a case where the first material layer is the whole layer, the first material layer is patterned to form the semiconductor layer after the induction is completed.

In some embodiments, the preset temperature is less than or equal to 400° C.

In some embodiments, a heating time is in a range of 0.5 h to 4 h.

In some embodiments, the metal is selected from one of or alloys consisting of aluminum, zinc, tin, tantalum, hafnium, zirconium and titanium.

In some embodiments, the metal oxide at least includes one or a combination of aluminum oxide, zinc oxide, tin oxide, tantalum oxide, hafnium oxide, zirconium oxide and titanium oxide.

In some embodiments, a heating atmosphere is an oxygen-containing atmosphere, an inert atmosphere or a vacuum atmosphere.

In some embodiments, forming the first material layer and the second material layer that are stacked on the substrate, includes: sequentially forming the first material layer and the second material layer on the substrate; or sequentially forming the second material layer and the first material layer on the substrate.

In some embodiments, in a case where the first material layer and the second material layer are sequentially formed on the substrate, the manufacturing method further includes: removing the second material layer after induction is completed.

In yet another aspect, an oxide semiconductor layer is provided. The oxide semiconductor layer is obtained by making a metal induced layer in contact with an oxide semiconductor, and performing annealing at a temperature ranging from 200° C. to 420° C. to cause the oxide semiconductor and the metal induced layer to crystallize or partially crystallize at an interface between the oxide semiconductor and the metal induced layer.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1A is a sectional diagram showing a structure of a thin film transistor, in accordance with some embodiments;

FIG. 1B is a schematic diagram of a thin film transistor transforming from a depletion layer to an inversion layer, in accordance with some embodiments;

FIG. 1C is a schematic diagram of a thin film transistor transitioning from a linear region to a saturation region, in accordance with some embodiments;

FIG. 1D is a graph of output characteristics of a thin film transistor under different gate voltages, in accordance with some embodiments;

FIG. 2A is a sectional diagram showing a structure of a bottom-gate thin film transistor, in accordance with some embodiments;

FIG. 2B is a sectional diagram showing a structure of another bottom-gate thin film transistor, in accordance with some embodiments;

FIG. 2C is a sectional diagram showing a structure of another bottom-gate thin film transistor, in accordance with some embodiments;

FIG. 2D is a sectional diagram showing a structure of another bottom-gate thin film transistor, in accordance with some embodiments;

FIG. 2E is a graph of I_{ds}^{1/2} versus V_{gs} (I_{ds}^{1/2}˜V_{gs}) made for a transfer characteristic curve, in accordance with some embodiments;

FIG. 2F is a sectional diagram showing a structure of another bottom-gate thin film transistor, in accordance with some embodiments;

FIG. 2G is a sectional diagram showing a structure of another bottom-gate thin film transistor, in accordance with some embodiments;

FIG. 2H is a sectional diagram showing a structure of a top-gate thin film transistor, in accordance with some embodiments;

FIG. 3A is a flow diagram of a manufacturing method for a thin film transistor, in accordance with some embodiments;

FIG. 3B is a sectional diagram showing a structure of another thin film transistor, in accordance with some embodiments;

FIG. 3C is a sectional diagram showing a structure of another thin film transistor, in accordance with some embodiments;

FIG. 3D is a sectional diagram showing a structure of another thin film transistor, in accordance with some embodiments;

FIG. 4A is a flow diagram of a manufacturing method for another thin film transistor, in accordance with some embodiments;

FIG. 4B is a sectional diagram showing a structure of another thin film transistor, in accordance with some embodiments;

FIG. 4C is a sectional diagram showing a structure of another thin film transistor, in accordance with some embodiments;

FIG. 4D is a sectional diagram showing a structure of another thin film transistor, in accordance with some embodiments;

FIG. 5A is a transmission electron microscope (TEM) image and an electron diffraction pattern of an Al/244 film, in accordance with some embodiments;

FIG. 5B is a photoelectron spectrum diagram of 244 TFT and Al/244-E TFT, in accordance with some embodiments;

FIG. 5C is a refractive index test chart of 244 TFT and Al/244-E TFT, in accordance with some embodiments;

FIG. 5D is a comparison diagram of transfer characteristic curves of 244 TFT, Al/244 TFT and Al/244-E TFT, in accordance with some embodiments;

FIG. 5E is a comparison diagram of transfer characteristic curves of 244 TFT under a negative gate bias stress (NBS) condition over time, in accordance with some embodiments;

FIG. 5F is a comparison diagram of transfer characteristic curves of Al/244 TFT under a NBS condition over time, in accordance with some embodiments;

FIG. 5G is a comparison diagram of transfer characteristic curves of Al/244-E TFT under a NBS condition over time, in accordance with some embodiments;

FIG. 6A is a TEM image and an electron diffraction pattern of a Zn/244 film, in accordance with some embodiments;

FIG. 6B is a comparison diagram of transfer characteristic curves of 244 TFT and Al/244 TFT, in accordance with some embodiments;

FIG. 6C is a comparison diagram of transfer characteristic curves of Zn/244 TFT under a NBS condition over time, in accordance with some embodiments;

FIG. 6D is a comparison diagram of transfer characteristic curves of 244 TFT, Hf/244 TFT and Ta/244 TFT, in accordance with some embodiments;

FIG. 7 is a comparison diagram of transfer characteristic curves of 244 TFT and ZnO/244 TFT, in accordance with some embodiments;

FIG. 8 is a comparison diagram of transfer characteristic curves of 244-N₂ TFT and Al/244-N₂ TFT, in accordance with some embodiments;

FIG. 9A is a comparison diagram of transfer characteristic curves of 424 TFT and Al/424 TFT, in accordance with some embodiments;

FIG. 9B is a comparison diagram of transfer characteristic curves of Pr:424 TFT and Al/Pr:424 TFT, in accordance with some embodiments;

FIG. 9C is a comparison diagram of transfer characteristic curves of Tb:424 TFT and Al/Tb:424 TFT, in accordance with some embodiments; and

FIG. 10 is a comparison diagram of transfer characteristic curves of IGZO TFT and Al/IGZO TFT, in accordance with some embodiments.

### DESCRIPTION OF THE INVENTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” as used herein indicates an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or values exceeding those stated.

Exemplary embodiments are described herein with reference to sectional views and/or plan views as idealized exemplary drawings. In the accompanying drawings, thicknesses of layers and sizes of regions are enlarged for clarity. Variations in shapes relative to the accompanying drawings due to, for example, manufacturing technologies and/or tolerances may be envisaged. Therefore, the exemplary embodiments should not be construed to be limited to the shapes of regions shown herein, but to include deviations in the shapes due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

Some embodiments of the present disclosure provide a display device. The display device includes a display panel. Of course, the display device may further include other components. For example, the display device may include a circuit for providing electrical signals for the display panel to drive the display panel for display. The circuit may be called a control circuit, and may include a circuit board and/or an integrated circuit (IC) electrically connected to the display panel.

For example, the display panel may be one of a liquid crystal display (LCD) panel, an organic light-emitting diode (OLED) display panel, a quantum dot light-emitting diode (QLED) display panel, a micro light-emitting diode (micro LED) display panel and a mini light-emitting diode (mini LED) display panel.

The display device may be a mobile phone, a tablet computer, a notebook computer, a personal digital assistant (PDA), a vehicle-mounted computer, a laptop computer, a digital camera, etc.

The display panel includes a base substrate and driving circuits (such as pixel driving circuits or gate driving circuits) provided on the base substrate. For example, the driving circuit may include thin film transistor(s) (TFT(s)). The thin film transistor(s) are important components for composing the pixel driving circuit or the gate driving circuit. During a power-on process, by controlling the thin film transistor(s) to be turned on or turned off, the pixel driving circuit and the gate driving circuit may be controlled to drive the display panel for display.

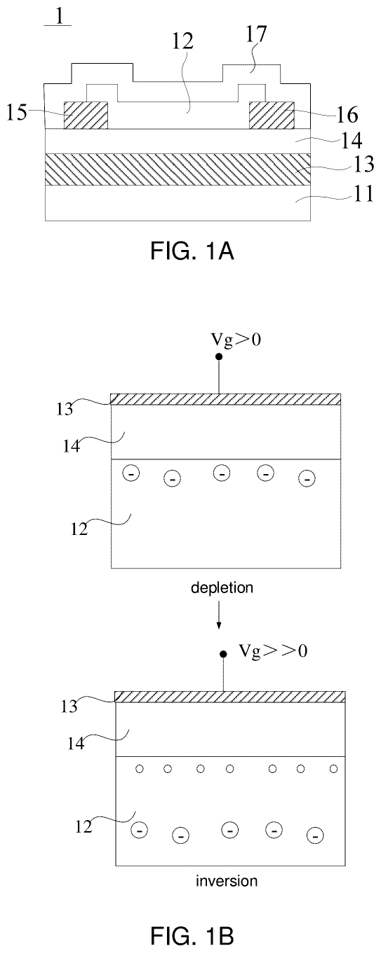

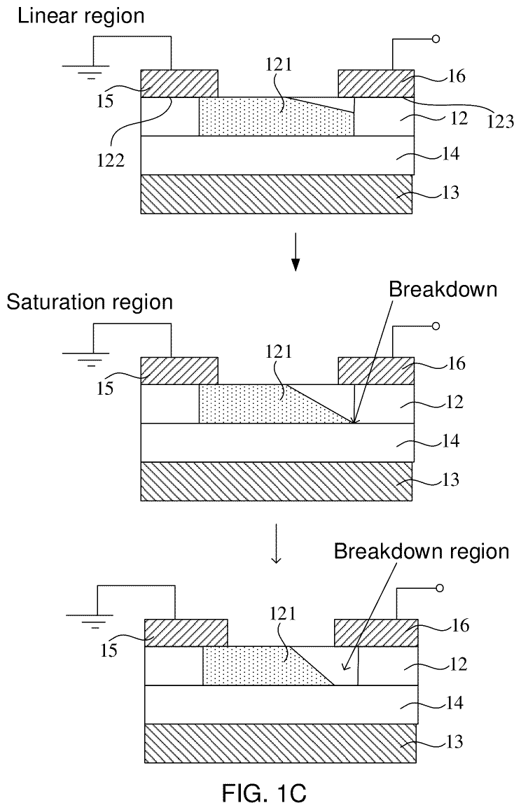

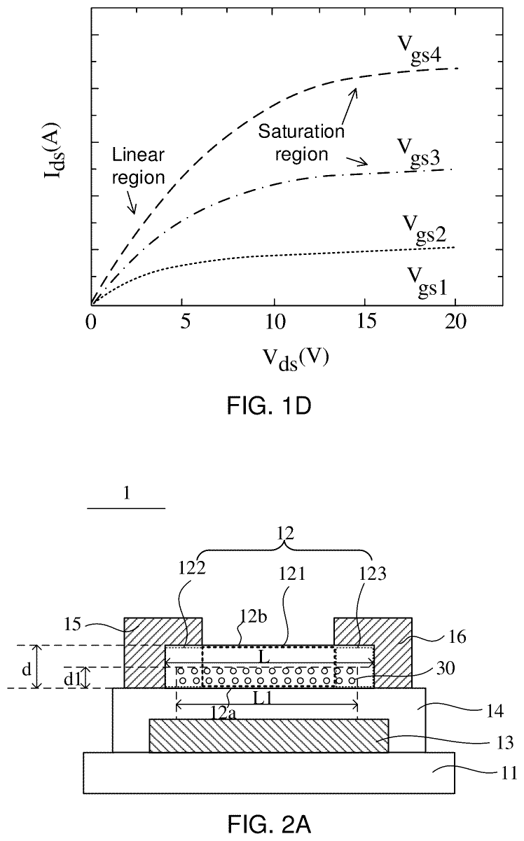

As shown in FIG. 1A, the thin film transistor 1 includes a substrate 11, and a semiconductor layer 12, a gate 13, a gate insulating layer 14, a source 15, a drain 16, and an insulating protective layer 17 that are provided on the substrate 11. The substrate 11 may be a portion of the above base substrate. Depending on that the above display panel is a flexible display panel or a rigid display panel, the substrate 11 may be a flexible substrate or a rigid substrate. For example, the flexible substrate may be a plastic substrate such as polyimide (PI), or a flexible substrate with a certain thickness made of glass or a metal material. For example, the rigid substrate may be a glass substrate or a semiconductor substrate (such as a silicon substrate or a corundum substrate). Of course, the substrate 11 may also be a substrate provided with other film layers (such as a metal layer, an insulation layer and/or a buffer layer) thereon. A material of the gate 13 may be a metal material or a semiconductor material. A material of the source 15 and the drain 16 may be a metal material or a metal oxide material. A material of the gate insulating layer 14 may be an insulating material such as silicon oxide, silicon nitride or a stacked material of silicon oxide and silicon nitride. A material of the insulating protective layer 17 may be an insulating material such as silicon oxide or silicon nitride.

In some embodiments, a material of the semiconductor layer 12 is a metal oxide semiconductor material. For example, the material of the semiconductor layer 12 may be a material containing indium (In), gallium (Ga), zinc (Zn), oxygen (O), tin (Sn) and other elements, such as indium gallium zinc oxide (IGZO), indium zinc oxide (IZO), indium tin oxide (InSnO or ITO), indium gallium tin oxide (InGaSnO or IGTO), indium zinc tin oxide (ITZO). These materials may also be doped with other elements to modify the semiconductor material, so as to improve mobility and/or bias stability of the semiconductor material. For example, these semiconductor materials may be doped with rare earth elements. That is, in embodiments of the present disclosure, the metal oxide semiconductor material may or may not be doped with the rare earth elements.

The rare earth elements are a general term for 17 special elements, and are named because that Swedish scientists used rare earth compounds when extracting the rare earth elements.

The rare earth elements include lanthanides, and elements yttrium (Y) and scandium (Sc) that are closely related to the lanthanides. The lanthanides refer to lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb) and lutetium (Lu), a total of 15 elements.

In some embodiments, the material of the semiconductor layer 12 is selected from any one of indium zinc tin oxide (ITZO) and indium gallium zinc oxide (IGZO), and indium zinc tin oxide (ITZO) and indium gallium zinc oxide (IGZO) are doped or not doped with rare earth elements.

In some embodiments, in a case where indium zinc tin oxide (ITZO) and indium gallium zinc oxide (IGZO) are doped with the rare earth elements, the rare earth elements are Pr or Tb.

A ratio of the number of atoms of all atoms in the above indium zinc tin oxide (ITZO) and indium gallium zinc oxide (IGZO) is not specifically limited.

In some embodiments, in a case where indium zinc tin oxide (ITZO) is selected as the material of the semiconductor layer 12, a ratio of the number of atoms of In, the number of atoms of Sn and the number of atoms of Zn in the indium zinc tin oxide (ITZO) is 4:2:4; or the ratio of the number of atoms of In, the number of atoms of Sn and the number of atoms of Zn in the indium zinc tin oxide (ITZO) is 2:4:4. Moreover, in a case where indium gallium zinc oxide (IGZO) is selected as the material of the semiconductor layer 12, a ratio of the number of atoms of In, the number of atoms of Ga and the number of atoms of Zn in the indium gallium zinc oxide (IGZO) is 1:1:1.

In some embodiments, a doping concentration of the rare earth elements is 2 at %. That is, in Pr-doped indium zinc tin oxide (ITZO), the doping concentration of Pr is 2 at %; in Tb-doped indium zinc tin oxide (ITZO), the doping concentration of Tb is 2 at %; in Pr-doped indium gallium zinc oxide (IGZO), the doping concentration of Pr is 2 at %, and in Tb-doped indium gallium zinc oxide (IGZO), the doping concentration of Tb is 2 at %.

In some other embodiments, the semiconductor layer 12 may be of a single-layer structure or a double-layer structure. In a case where the semiconductor layer has a double-layer structure, each layer in the double-layer structure has a different material.

Considering an n-type thin film transistor 1 as an example, a working principle of the thin film transistor 1 is as follows.

As shown in FIG. 1B, when a positive voltage is applied to the gate 13, a gate voltage generates an electric field in the gate insulating layer 14, electric force lines are directed from the gate 13 to a surface of the semiconductor, and induced charges are created at the surface. As the gate voltage increases, the surface of the semiconductor will transform from a depletion layer to an electron accumulation layer to become an inversion layer. When a strong inversion is reached (the required gate voltage V_{gs} is called a threshold voltage Vₜₕ of the thin film transistor, i.e., reaching a turn-on voltage), if a voltage is applied between the source 15 and the drain 16, carriers will pass through the channel. As shown in FIGS. 1C and 1D, when a source-drain voltage V_{ds} is very small, the conductive channel is approximately a constant resistance, and a leakage current increases linearly as the source-drain voltage V_{ds} increases, corresponding to a linear region of the thin film transistor 1. When the source-drain voltage V_{ds} is very large, the source-drain voltage V_{ds} will affect the gate voltage, which causes the electric field in the gate insulating layer 14 to gradually weaken from an end of the source to an end of the drain, and electrons in the inversion layer on the surface of the semiconductor to gradually decrease from the end of the source to the end of the drain. Therefore, the resistance of the channel increases as the source-drain voltage V_{ds} increases. The increase of the leakage current I_{ds} becomes slow, corresponding to transition from the linear region to a saturation region. When the source-drain voltage V_{ds} increases to a certain level, a thickness of the inversion layer at the end of the drain is reduced to zero. As the source-drain voltage V_{ds} continues to increase, the device (i.e., the thin film transistor) enters the saturation region.

Therefore, a working region of the turned-on thin film transistor 1 is divided into a non-saturation, a critical saturation point and a saturated region. In a case where V_{gs} is greater than Vₜₕ (V_{gs}>Vₜₕ) and V_{ds} is less than a difference between V_{gs} and Vₜₕ (V_{ds}<V_{gs}−Vₜₕ), the thin film transistor 1 works in the non-saturation, and the corresponding current of the non-saturation is shown in the following formula (1). In a case where V_{ds} is greater than a difference between V_{gs} and Vₜₕ (V_{ds}>V_{gs}−Vₜₕ) and V_{gs} is greater than Vₜₕ (V_{gs}>Vₜₕ), the thin film transistor 1 works in the saturation region, and the corresponding current of the saturation region is shown in the following formula (2). In the formulas, u is electron mobility (also called carrier mobility), Cₒₓ is a capacitance per unit area of the metal-insulating layer-semiconductor (MIS) structure of the thin film transistor, and W/L represents a ratio of a channel width to a channel length of the thin film transistor. Of course, in a case where an inversion channel is not formed, the thin film transistor is in a cutoff region.

$${I}_{ds} = μ \cdot {C}_{ox} \cdot \frac{W}{L} ( {V}_{gs} - {V}_{th} - \frac{1}{2} {V}_{ds} ) {V}_{ds} . \qquad ( 1 )$$

$${I}_{ds} = \frac{1}{2} μ \cdot {C}_{ox} \cdot \frac{W}{L} {( {V}_{gs} - {V}_{th} )}^{2} . \qquad ( 2 )$$

In the liquid crystal display panel, the thin film transistor 1 works in the non-saturation region most of the time. It can be seen from the formula (1) that in order to increase an on-state current of the thin film transistor 1, values of μ, Cₒₓ, W/L, V_{gs} and V_{ds} may be increased, or a value of Vₜₕ may be decreased.

For amorphous metal oxide semiconductor materials, there are a large number of micropores and defects in a first material layer 10 (for forming the semiconductor layer 12), and an atomic arrangement is low in order degree. As a result, the electron mobility of the thin film transistor 1 using the amorphous metal oxide semiconductor material as the channel may be greatly affected, which is not conducive to improving the performance of the thin film transistor 1.

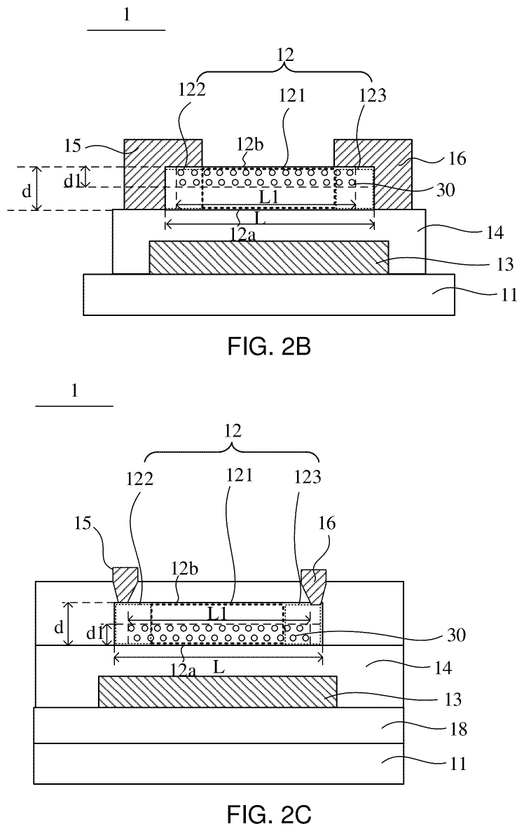

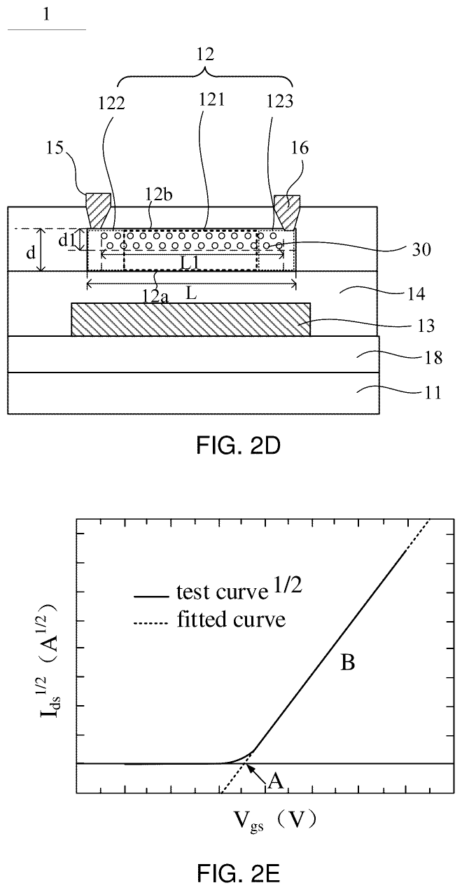

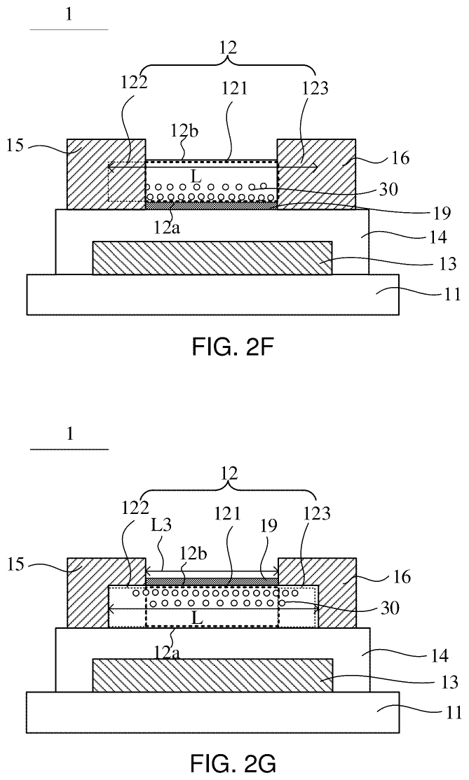

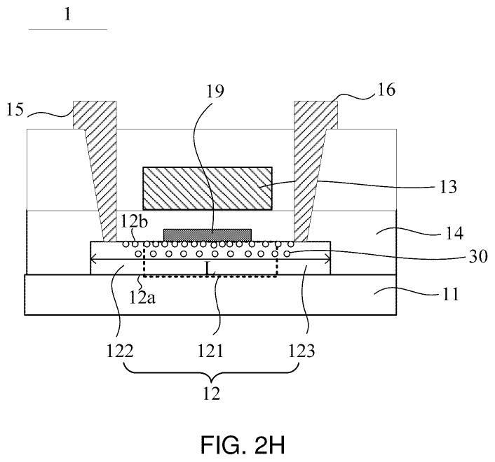

In some embodiments, as shown in FIGS. 2A, 2B, 2C and 2D, the semiconductor layer 12 includes a first surface 12a proximate to the substrate 11 and a second surface 12b away from the substrate 11. The semiconductor layer 12 has a channel region 121, and a source region 122 and a drain region 123 that are located on two opposite sides of the channel region 121. The semiconductor layer 12 is provided with crystals 30 of metal oxide semiconductor at least in the channel region 121 and proximate to the first surface 12a or the second surface 12b. The source 15 of the thin film transistor 1 is in contact with the source region 122, and the drain 16 of the thin film transistor 1 is in contact with the drain region 123.

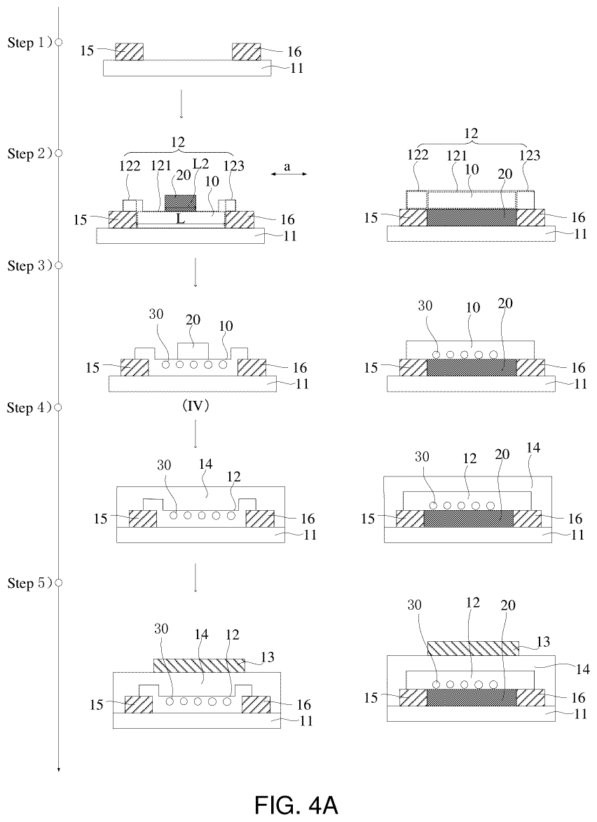

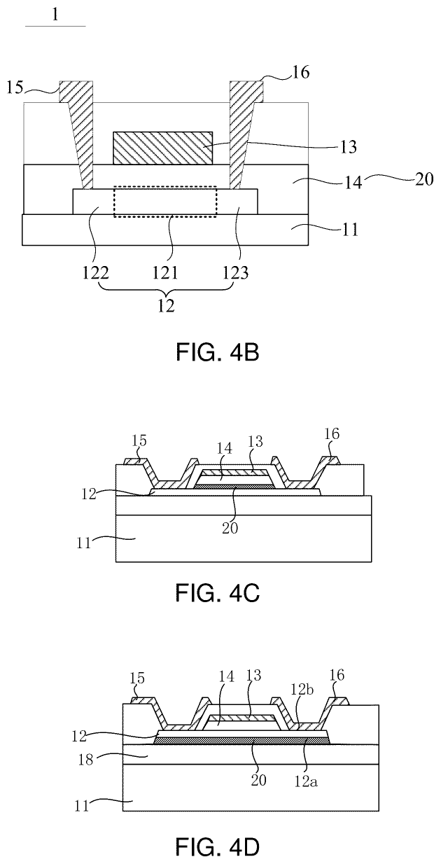

Considering the thin film transistor 1 being a bottom-gate thin film transistor as an example, as shown in FIGS. 1, 2A and 2B, the first surface 12a is a surface of the semiconductor layer 12 proximate to the gate insulating layer 14, and the second surface 12b is a surface of the semiconductor layer 12 proximate to the insulating protective layer 17. Considering the thin film transistor 1 being a top-gate thin film transistor as an example, as shown in FIG. 4D, the first surface 12a is a surface of the semiconductor layer 12 proximate to a buffer layer 18 on the substrate 11, and the second surface 12b is a surface of the semiconductor layer 12 proximate to the gate insulating layer 14.

In these embodiments, the crystals 30 of metal oxide semiconductor are formed at least in the channel region 121 of the semiconductor layer 12 and proximate to the first surface 12a or the second surface 12b. Compared with a case that the metal oxide semiconductor material of the semiconductor layer 12 is an amorphous oxide, the atomic order degree of the metal oxide semiconductor in the semiconductor layer 12 may be improved. With the improvement of the atomic order degree, overlap of electron clouds between atoms may increase, thereby reducing the scattering effect of the electrons during transportation and improving electron mobility. In addition, the improvement of the atomic order degree may reduce various structural defects and is also conducive to improving the field effect mobility and stability of the thin film transistor 1.

Moreover, a transfer characteristic curve of the thin film transistor 1 is tested, and as shown in FIG. 2E, a graph of I_{ds}^{1/2} versus V_{gs} (I_{ds}^{1/2}˜V_{gs}) is made for the transfer characteristic curve according to the formula of the transfer characteristic saturation region. The formula is shown in the following formula (3). By fitting the straight line segment, the electron mobility μ and the threshold voltage Vₜₕ may be extracted according to a slope of an extrapolated curve. The calculation formula of u can be shown in the following formula (4), and combined with formula (3) and FIG. 2E, in a case where las is equal to 0 (I_{ds}=0), there is a relationship of Vₜₕ is equal to V_{gs} (Vₜₕ=V_{gs}). In this case, the value of Vₜₕ is a value of an abscissa corresponding to point A. It is found through calculation that compared with a case that the electron mobility of the thin film transistor 1 is in a range of 5 cm²/Vs to 30 cm²/Vs without the crystals 30 of metal oxide semiconductor generated, after the crystals 30 of metal oxide semiconductor are formed in the first material layer 10, the electron mobility of thin film transistor 1 increases to more than 40 cm²/Vs, and the threshold voltage remains around 0V. Thus, it is further proved that after the crystals 30 of metal oxide semiconductor are formed, micropores and defects in the first material layer 10 may be reduced, thereby increasing the electron mobility μ and reducing the threshold voltage Vₜₕ of the thin film transistor 1.

$$\sqrt{{I}_{ds}} = \sqrt{\frac{W}{2 L} \cdot μ \cdot {C}_{OX}} ( {V}_{gs} - {V}_{th} ) . \qquad ( 3 )$$

$$B = \sqrt{\frac{W}{2 L} \cdot μ \cdot {C}_{OX}} and$$

$$μ = \frac{2 {B}^{2}}{( W / L ) {C}_{OX}} . \qquad ( 4 )$$

In some embodiments, as shown in FIGS. 2A, 2B, 2C and 2D, a thickness d1 of the crystals 30 in the semiconductor layer 12 is greater than or equal to ¼ of a thickness of the semiconductor layer 12 and less than or equal to the thickness d of the semiconductor layer 12.

It is found through experiments that by controlling the thickness d1 of the crystals 30 in the semiconductor layer 12 within the above range, the carrier mobility of the thin film transistor 1 may increase by more than 200%.

In some embodiments, as shown in FIGS. 2A, 2B, 2C and 2D, a dimension L1 of a distribution range of the crystals 30 in a direction of a length L of the channel is greater than or equal to ½ of the length L of the channel. Here, since the crystals 30 are preferentially formed on the first surface 12a or the second surface 12b of the semiconductor layer 12, there may be a situation that the dimension of the distribution range of the crystals 30 in the direction of the length of the channel is maximum at a position proximate to the first surface 12a or the second surface 12b of the semiconductor layer 12, and as being farther away from the first surface 12a or the second surface 12b of the semiconductor layer 12, the dimension L1 of the distribution range of the crystals 30 in the direction of the length of the channel presents a gradually decreasing trend. Therefore, the dimension L1 of the distribution range of the crystals 30 in the direction of the length of the channel is defined as the above maximum dimension, that is, the dimension of the distribution range of the crystals 30 at a position closest to the first surface 12a or the second surface 12b of the semiconductor layer 12 in the direction of the length of the channel.

In these embodiments, by controlling the distribution range of the crystals 30 within the above range, the carrier mobility of the entire channel region 121 may increase, thereby greatly improving the electron mobility of the thin film transistor 1.

In some embodiments, as shown in FIGS. 2F and 2G, the thin film transistor 1 further includes a metal oxide layer 19. The metal oxide layer 19 covers at least a middle of the channel region 121 in the direction of the length L of the channel, and a dimension L3 of the metal oxide layer 19 in the direction of the length L of the channel is greater than or equal to ½ of the length L of the channel. The metal oxide layer 19 is in contact with the semiconductor layer 12.

In these embodiments, the metal oxide layer 19 may be a material layer obtained after inducing the semiconductor layer 12 to generate the crystals 30 in the semiconductor layer 12. For example, a material of the metal oxide layer 19 may be obtained from a metal material before induction. During induction, the metal material is transformed into a metal oxide by introducing an oxygen-containing gas, thereby avoiding introducing an additional conductive layer in the thin film transistor 1 or directly using the metal oxide layer 19 as an induction layer to induce the semiconductor layer 12.

In some embodiments, the metal oxide layer 19 is disposed between the gate insulating layer 14 and the semiconductor layer 12. As shown in FIG. 2F, in a case where the thin film transistor 1 is a bottom-gate thin film transistor, the metal oxide layer 19 is provided on a side where the first surface 12a is located. As shown in FIG. 2H, in a case where the thin film transistor 1 is a top-gate thin film transistor, the metal oxide layer 19 is provided on a side where the second surface 12b is located.

That is, the metal oxide layer 19 is provided on a side of the semiconductor layer 12 proximate to the gate insulating layer 14.

Of course, in some other embodiments, the metal oxide layer 19 may alternatively be disposed on a side of the semiconductor layer 12 away from the gate insulating layer 14. In this case, the metal oxide layer 19 may be provided between the buffer layer 18 and the semiconductor layer 12 (for the top-gate thin film transistor). Alternatively, the thin film transistor 1 further includes an interlayer insulating layer, and the metal oxide layer 19 is provided between the semiconductor layer 12 and the interlayer insulating layer.

In some embodiments, in the semiconductor layer 12, a distribution density of the crystals 30 gradually increases in a direction gradually approaching the metal oxide layer 19.

Considering an example of the metal oxide layer 19 being provided between the semiconductor layer 12 and the gate insulating layer 14, in the direction gradually approaching the metal oxide layer 19, the crystals have an increasing sense of distribution and an increasing number.

In some embodiments, the crystal 30 is a ZnSO₃ crystal. It can be founded through electron diffraction pattern analysis that the electron diffraction pattern of the crystal is consistent with the electron diffraction pattern of ZnSO₃ crystal. It can be observed through transmission electron microscopy that the morphology of the crystal is spherical.

In some embodiments, an oxygen vacancy concentration of the semiconductor layer 12 is less than or equal to 10%. The oxygen vacancy concentration refers to a proportion of the number of oxygen vacancies to the total number of theoretical oxygen atoms in the entire semiconductor layer 12. That is, considering an example where the material of the semiconductor layer 12 is ITZO, and a ratio of the number of atoms of In, the number of atoms of Sn, the number of atoms of Zn and the number of atoms of O is 4:2:4:14, the total number of theoretical oxygen atoms in the semiconductor layer 12 is the number of the oxygen atoms in the ITZO obtained by calculation according to the above ratio and the mass of the sputtered ITZO.

In these embodiments, after the crystals 30 are formed, the oxygen vacancy concentration may be significantly reduced compared with a case that the metal oxide semiconductor material of the semiconductor layer 12 is an amorphous oxide. The reason is that the generation of crystals 30 in the semiconductor layer 12 may effectively remove structural defects in the amorphous oxide, thereby reducing the oxygen vacancy concentration. As the oxygen vacancy concentration decreases, the bias stability of the thin film transistor 1 may be improved, and thus negative drift of the threshold voltage of the thin film transistor 1 under a negative gate bias stress (NBS) may be reduced.

In some embodiments, a drift amount of the threshold voltage of the thin film transistor 1 under the negative gate bias stress is less than or equal to 1 V. The test condition for the negative gate bias stress is that a gate bias is −20 V and the time is 3600 s.

Here, it will be noted that, for an n-type thin film transistor, the threshold voltage of the thin film transistor under the negative gate bias stress may drift negatively. Therefore, the drift amount of the threshold voltage of the thin film transistor 1 under the negative gate bias stress is usually written as a negative number, which represents a drift direction. For example, the drift amount of the threshold voltage of the thin film transistor 1 under the negative gate bias stress is less than or equal to 1 V, which is written in the following embodiments as that the drift amount ΔVₜₕ of the threshold voltage of the thin film transistor 1 under the negative gate bias stress is less than or equal to −1 V, which means that the drift amount ΔVₜₕ of the threshold voltage of the thin film transistor 1 under the negative gate bias stress is any value from −1 V to 0 V.

In some embodiments, a subthreshold swing of the thin film transistor 1 is less than or equal to 0.3 V/decade. The subthreshold swing may be obtained from the transfer characteristic curve. It is found through testing that in a case where the semiconductor layer 12 is provided with the crystals 30 therein, the subthreshold swing of the thin film transistor 1 may be greatly reduced.

In some embodiments, an on/off current ratio Iₒₙ/I_{off} of the thin film transistor 1 is greater than or equal to 1.0×10⁷ A. It is found through testing that in a case where the semiconductor layer 12 is provided with the crystals 30 therein, the on/off current ratio Iₒₙ/I_{off} of the thin film transistor 1 is relatively large, and the performance of the thin film transistor 1 may be improved.

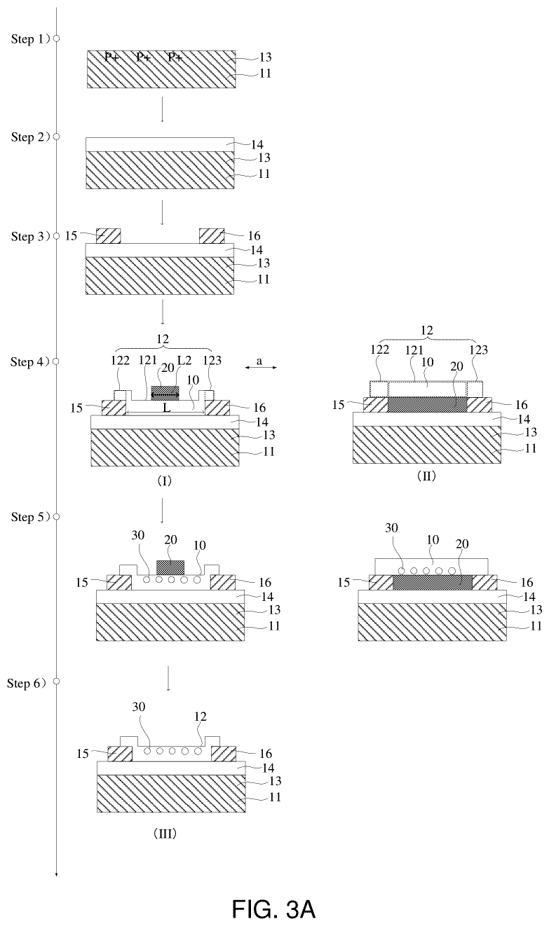

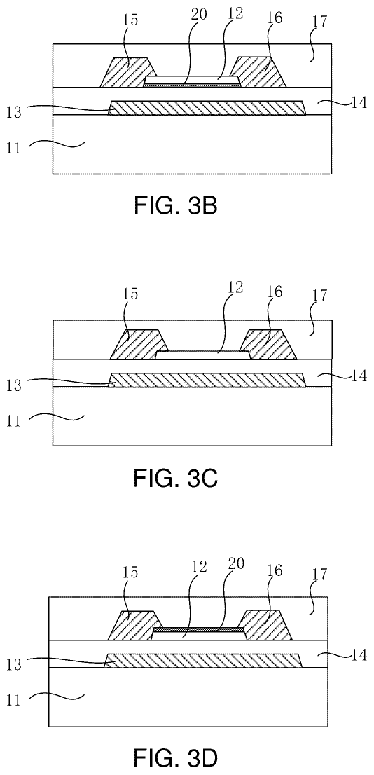

Some embodiments of the present disclosure provide a manufacturing method for a thin film transistor. The thin film transistor 1 includes a semiconductor layer 12, and the semiconductor layer 12 has a channel region 121. As shown in FIG. 3A, the manufacturing method includes the following steps.

In step 1), a gate 13 is formed on a substrate 11.

Considering the substrate 11 being a semiconductor substrate as an example, the substrate 11 may be a silicon substrate. In this case, silicon may be performed p-type heavy doping, and the p-type heavily doped silicon may be used as the substrate 11 and the gate 13. The gate 13 may be a whole layer, or may have a certain pattern. FIG. 3A shows a case that the gate 13 is the whole layer, that is, an entire surface of the silicon substrate is performed p-type heavy doping to obtain the gate 13. The total thickness of the substrate 11 and the gate 13 may be 500 μm.

It will be noted that only the case of using the p-type heavily doped silicon as the substrate 11 and the gate 13 is shown here. It may be understood by those skilled in the art that the material of the gate 13 may also be a metal material, such as a single-layer or multi-layer composite stack formed by one or more materials of molybdenum (Mo), niobium (Nb), aluminum (Al), neodymium (Nd), titanium (Ti) and copper (Cu).

In step 2), a gate insulating layer 14 is formed on the substrate 11 on which the gate 13 is formed.

The gate insulating layer 14 may be a silicon dioxide film grown on the silicon substrate. As shown in FIG. 3A, the silicon dioxide film may also be a whole layer. The thickness of the silicon dioxide film may be in a range of 50 nm to 300 nm, inclusive.

Of course, the material of the gate insulating layer 14 may be, in addition to silicon dioxide, other insulating materials, such as silicon nitride or a stacked material of silicon nitride and silicon dioxide.

In step 3), a source 15 and a drain 16 are formed on the substrate 11 on which the gate insulating layer 14 is formed.

The material of the source 15 and the drain 16 may be a metal material such as a single-layer or multi-layer composite stack formed by one or more materials of molybdenum (Mo), niobium (Nb), aluminum (Al), neodymium (Nd), titanium (Ti), copper (Cu) and gold. Alternatively, the material of the source 15 and the drain 16 may be a metal oxide conductive material such as indium tin oxide (ITO). The material of the source 15 and the drain 16 is not specifically limited here.

Here, considering the material of the source 15 and the drain 16 being ITO as an example, an ITO film with a thickness ranging from 50 nm to 300 nm may be deposited by magnetron sputtering, and the source 15 and the drain 16 are formed by a patterning process after deposition.

The radio frequency (RF) power of the magnetron sputtering may be in a range of 30 W to 120 W, the argon flow may be in a range of 20 sccm to 50 sccm (standard cubic centimeter per minute), the oxygen flow may be in a range of 1 sccm to 5 sccm, and the working pressure may be in a range of 0.10 Pa to 0.50 Pa.

In step 4), a first material layer 10 and a second material layer 20 that are stacked are formed on the substrate 11 on which the source 15 and the drain 16 are formed. The first material layer 10 is a whole layer; alternatively, the first material layer 10 has the same pattern as the semiconductor layer 12. An orthographic projection of the second material layer 20 on the substrate 11 at least covers a middle of the first material layer 10 corresponding to the channel region 121 in a direction (a direction indicated by the arrow a in FIG. 3A) of a length L of the channel, and a dimension L2 of the orthographic projection of the second material layer 20 on the substrate 11 in the direction of the length L of the channel is greater than or equal to ½ of the length L of the channel. The material of the first material layer 10 is a metal oxide semiconductor material, and the material of the second material layer 20 is a metal or a metal oxide.

For example, the metal oxide semiconductor material may be a material containing indium (In), gallium (Ga), zinc (Zn), oxygen (O), tin (Sn) and other elements, such as indium gallium zinc oxide (IGZO), indium zinc oxide (IZO), indium tin oxide (InSnO or ITO), indium gallium tin oxide (InGaSnO or IGTO), indium zinc tin oxide (ITZO). These semiconductor materials may also be doped with other elements such as rare earth elements.

In a case where the material of the second material layer 20 is a metal, from a perspective of reaction kinetics, the metal may provide additional electrons to promote dangling bonds, H—O bonds and weak M(metal)-O bonds of the first material layer 10 near an interface of the first material layer 10 proximate to the second material layer 20 to be preferentially broken; and from a perspective of Gibbs free energy, the metal is more inclined to seize weak bonded oxygen. These will all play an inducing role, so as to cause atoms of the material of the first material layer 10 to rearrange driven by a relatively low thermal energy.

In a case where the material of the second material layer 20 is a metal oxide, oxygen vacancies in the metal oxide will also migrate to the adjacent first material layer 10, and the weak bonded oxygen in the first material layer 10 will also migrate to the metal oxide, which may also play an inductive role.

In some embodiments, the metal is selected from one of or alloys consisting of aluminum, zinc, tin, tantalum, hafnium, zirconium and titanium.

A lattice structure of aluminum is a face-centered cubic lattice structure, a lattice structure of zinc is a hexagonal lattice structure, a lattice structure of tin is a tetragonal lattice structure, a lattice structure of tantalum is a body-centered cubic lattice structure, a lattice structure of hafnium is a hexagonal lattice derived structure below 1300°, a lattice structure of zirconium is a hexagonal lattice structure, and a lattice structure of titanium is a hexagonal lattice structure.

In these embodiments, in a case where the metal is selected from one or more of aluminum, tin and tantalum, the annealing (induction) temperature is relatively high. However, after some crystals 30 are generated in the first material layer 10, mobility and bias stability of the device may be greatly improved. In a case where the metal is selected from one or more of zinc, hafnium, zirconium and titanium, these metals have relatively good diffusivity and relatively high solid solubility in the first material layer 10, and may crystallize at relatively low temperature. Therefore, the field effect mobility of the thin film transistor 1 may be significantly improved.

In some embodiments, the metal oxide at least includes one or a combination of aluminum oxide, zinc oxide, tin oxide, tantalum oxide, hafnium oxide, zirconium oxide and titanium oxide.

These metal oxides may all play an inducing role similar to the corresponding metals (e.g., the corresponding metal of aluminum oxide is aluminum, and the corresponding metal of zinc oxide is zinc), so that the crystals 30 of metal oxide semiconductor may be formed in the first material layer 10, and the field effect mobility and bias stability of the thin film transistor 1 may also be improved.

In a case where the first material layer 10 is a whole layer, an orthographic projection of the first material layer 10 on the substrate 11 is completely overlapped with the substrate 11. In this case, the first material layer 10 may be a metal oxide semiconductor film. In a case where the first material layer 10 has the same pattern as the semiconductor layer 12, the orthographic projection of the first material layer 10 on the substrate 11 is partially overlapped with the substrate 11. In this case, a metal oxide semiconductor film may be first formed (e.g., the metal oxide semiconductor film may be formed by magnetron sputtering) on the substrate 11 on which the gate insulating layer 14 is formed, and then the first material layer 10 is formed by a patterning process (i.e., a process for patterning, which may include steps of photoresist coating, exposure, development and etching).

In these embodiments, the orthographic projection of the second material layer 20 on the substrate 11 at least covers the middle of the first material layer 10 corresponding to the channel region 121 in the direction of the length L of the channel, and the dimension L2 of the orthographic projection of the second material layer 20 on the substrate 11 in the direction of the length of the channel is greater than or equal to ½ of the length L of the channel. Therefore, during induction, the crystals 30 of metal oxide semiconductor may be preferentially formed at the middle of the first material layer 10 corresponding to the channel region 121 in the direction of the length L of the channel, and it can be ensured that a dimension L1 of a distribution range of the crystals 30 in the direction of the length L of the channel is greater than or equal to ½ of the length L of the channel. As a result, an order degree of atomics of the metal oxide semiconductor material in the direction of the length L of the channel may be improved, the conductivity of the metal oxide semiconductor material in the direction of the length L of the channel may further be improved, and the electron mobility of the thin film transistor 1 may be improved.

The positional relationship between the first material layer 10 and the second material layer 20 is not specifically limited. The second material layer 20 may be disposed above or below the first material layer 10.

Based on this, forming the first material layer 10 and the second material layer 20 that are stacked on the substrate 11 may include: as shown in step 4) in FIG. 3A, sequentially forming the first material layer 10 and the second material layer 20 on the substrate 11 to obtain the structure shown in (I) in FIG. 3A, or sequentially forming the second material layer 20 and the first material layer 10 on the substrate 11 to obtain the structure shown in (II) in FIG. 3A.

In a case where the first material layer 10 and the second material layer 20 are sequentially formed on the substrate 11, the second material layer 20 is located above the first material layer 10. In a case where the second material layer 20 and the first material layer 10 are sequentially formed on the substrate 11, the second material layer 20 is located below the first material layer 10.

In step 5), the first material layer 10 and the second material layer 20 are heated, so that the second material layer 20 induces the first material layer 10 to form crystals 30 of metal oxide semiconductor at least on a surface proximate to the second material layer 20 at a preset temperature. The preset temperature is greater than or equal to 200° C. and less than or equal to 420° C.

The above heating atmosphere is not specifically limited, as long as the second material layer 20 can seize the weak bonded oxygen in the metal oxide semiconductor material to cause atoms of the metal oxide semiconductor material to rearrange under the heating condition.

In some embodiments, the heating atmosphere is an oxygen-containing atmosphere, an inert atmosphere, or a vacuum atmosphere.

The oxygen-containing atmosphere may be, for example, an air atmosphere, and the inert atmosphere may be, for example, a nitrogen atmosphere, a helium atmosphere or a neon atmosphere.

In some embodiments, in a case where the material of the second material layer 20 is a metal, the second material layer 20 is formed above the first material layer. In addition, after the induction is completed, the manufacturing method further includes: as shown in step 6) in FIG. 3A, removing the second material layer 20 to obtain the structure shown in (III) in FIG. 3A.

In some other embodiments, in a case where the material of the second material layer 20 is a metal oxide, the second material layer 20 may be formed above or below the first material layer 10.

Here, it will be noted that in a case where the second material layer 20 is formed below the first material layer 10, a dimension L2 of the orthographic projection of the second material layer 20 on the substrate 11 in the direction of the length L of the channel may be equal to the length L of the channel. That is, the second material layer 20 is filled between the source 15 and the drain 16; and in this case, the second material layer 20 may be used as the gate insulating layer 14 or a part of the gate insulating layer 14. Alternatively, the second material layer 20 has the same pattern with the gate insulating layer 14 and is located between the gate insulating layer 14 and the semiconductor layer 12, and in this case, the second material layer 20 is the above metal oxide layer. In a case where the second material layer 20 is formed above the first material layer 10, after the induction is completed, the second material layer 20 may or may not be removed. In a case where the second material layer 20 is not removed, the second material layer 20 may be used as the insulating protective layer 17 or a part of the insulating protective layer 17. In this case, the second material layer 20 may also be the above metal oxide layer.

In some embodiments, in a case where the first material layer 10 is a whole layer, the manufacturing method further includes: after the induction is completed, patterning the first material layer 10 to form the semiconductor layer 12.

Here, there are two possible implementations. In the first implementation, as shown in (I) in step 4) in FIG. 3A, the second material layer 20 is formed above the first material layer 10. In this case, the second material layer 20 may be a whole layer; alternatively, the second material layer 20 may have a certain pattern. In a case where the second material layer 20 is the whole layer, after the induction is completed, the semiconductor layer 12 and the induction pattern may be formed through the same patterning process. The induction pattern may have the same pattern as the semiconductor layer 12. In this case, the material of the second material layer 20 may be an insulating material (such as a metal oxide) or a conductive material. In a case where the material of the second material layer 20 is the insulating material, the second material layer 20 may or may not be removed. In a case where the second material layer 20 is not removed, the second material layer 20 may be used as the insulating protective layer 17 or a part of the insulating protective layer 17; alternatively, the second material layer 20 has the same pattern as the channel region 121 and is located between the insulating protective layer 17 and the first material layer 10, and in this case, the second material layer 20 is the above metal oxide layer. In a case where the material of the second material layer 20 is a conductive material, the second material layer 20 is removed. Of course, in the case where the material of the second material layer 20 is the conductive material, after the induction is completed, the second material layer 20 may also be removed first, and then the semiconductor layer 12 is formed by patterning. In a case where the second material layer 20 has a certain pattern, there are two possible cases. In the first case, the dimension L2 of the orthographic projection of the second material layer 20 on the substrate 11 in the direction of the length L of the channel is greater than a dimension of the semiconductor layer 12 in the direction of the length L of the channel. In this case, the first material layer 10 is patterned, and reference may be made to the above operation in a case where the second material layer 20 is the whole layer. In the second case, the dimension L2 of the orthographic projection of the second material layer 20 on the substrate 11 in the direction of the length L of the channel is less than or equal to the dimension of the semiconductor layer 12 in the direction of the length L of the channel. After the induction is completed, the semiconductor layer 12 may be formed directly by patterning. In this case, similar to the above description, in a case where the material of the second material layer 20 is an insulating material (such as a metal oxide), after the induction is completed, the second material layer 20 may or may not be removed, and details may refer to the above description. In a case where the material of the second material layer 20 is a conductive material, the second material layer 20 is removed.

In the second implementation, as shown in (II) in step 4) in FIG. 3A, the second material layer 20 is formed below the first material layer 10. In this case, the second material layer 20 has a certain pattern. For example, the orthographic projection of the second material layer 20 on the substrate 11 covers the middle of the channel region 121 in the direction of the length L of the channel, and the dimension L2 of the orthographic projection of the second material layer 20 on the substrate 11 in the direction of the length L of the channel is greater than or equal to ½ of the length L of the channel and less than or equal to the length L of the channel. In this case, after the induction is completed, the semiconductor layer 12 may be formed directly by patterning. The material of the second material layer 20 may be an insulating material or a material that can be formed into an insulating material by an induction process. In this case, the second material layer 20 may be used as the gate insulating layer 14 or a part of the gate insulating layer 14. Alternatively as shown in (II) in FIG. 3A, the second material layer 20 has the same pattern as the channel region 121 and is located between the gate insulating layer 14 and the first material layer 10. In this case, the second material layer 20 may also be the above metal oxide layer.

The above description introduces a case where the source 15 and the drain 16 are disposed on a side of the semiconductor layer 12 proximate to the substrate 11. In a case where the source 15 and the drain 16 are disposed on a side of the semiconductor layer 12 away from the substrate 11, steps 4) and 5) occur before step 3). In this case, the second material layer 20 may also be formed below or above the first material layer 10. In a case where the second material layer 20 is formed below the first material layer 10, the second material layer 20 may be a whole layer or have a certain pattern. In this case, the second material layer 20 may be directly used as the gate insulating layer 14 or a part of the gate insulating layer 14. Alternatively, as shown in FIG. 3B, the second material layer 20 has the same pattern as the semiconductor layer 12 and is located between the gate insulating layer 14 and the first material layer 10. In a case where the second material layer 20 is formed above the first material layer 10, the second material layer 20 may or may not be removed. In a case where the second material layer 20 is removed, the structure shown in FIG. 3C is obtained. In a case where the second material layer 20 is not removed, the second material layer 20 may be directly used as an interlayer insulating layer or the insulating protective layer 17. In a case where the second material layer 20 is the whole layer, via holes may be provided in the second material layer 20 (as the interlayer insulating layer) at positions corresponding to a source region 122 and a drain region 123, so that the source 15 is in contact with the source region 122 and the drain 16 is in contact with the drain region 123. In a case where the second material layer 20 has a certain pattern, the second material layer 20 may only cover the channel region 121; alternatively, as shown in FIG. 3D, the second material layer 20 has the same pattern as the semiconductor layer 12. In a case where the second material layer 20 only covers the channel region, the source 15 and the drain 16 may be directly formed on the source region and drain region of the semiconductor layer 12. In a case where the second material layer 20 has the same structure as the semiconductor layer 12, as shown in FIG. 3D, the source 15 and the drain 16 may be in contact with sides of the semiconductor layer 12 to achieve electrical connection.

Of course, in some embodiments, the manufacturing method may further include a step of forming the insulating protective layer 17.

The manufacturing method for the thin film transistor provided by embodiments of the present disclosure provides the second material layer 20 and utilizes an induction effect of the second material layer 20 to cause atoms of the metal oxide semiconductor material to rearrange driven by a relatively low thermal energy. Therefore, the electron mobility and bias stability of the thin film transistor 1 may be improved, and the threshold voltage of the thin film transistor 1 may be reduced, thereby improving overall performance of the thin film transistor.

In addition, in the embodiments of the present disclosure, by setting the heating temperature to be in a range of 200° C. to 420° C., the heat treatment temperature of the first material layer 10 and the second material layer 20 may be reduced to the greatest extent. Thus, the overall performance of the thin film transistor 1 may be improved, and the process temperature during manufacturing the thin film transistor 1 may be reduced. This may be applied to the manufacture of flexible display panels, thereby meeting application requirements.

In some embodiments, in order to further meet application requirements, the preset temperature is less than or equal to 400° C., and thus the heating temperature may be further reduced.

In some embodiments, the heating time is in a range of 0.5 h to 4 h. It is found through experiments that by controlling the heating time within the above range, the crystals 30 with a certain thickness may be obtained, thereby improving electron mobility and bias stability.

In some other embodiments, in order to save manufacturing costs, the heating atmosphere may be an air atmosphere or a vacuum atmosphere.

The above description introduces the manufacturing method of the bottom-gate thin film transistor. The manufacturing method of the top-gate thin film transistor will be described below. As shown in FIG. 4A, the manufacturing method includes the following steps.

In step 1), a source 15 and a drain 16 are formed on a substrate 11.

The manufacturing method of the source 15 and the drain 16 may refer to the manufacturing method of the source 15 and the drain 16 in the bottom-gate thin film transistor. The substrate 11 may be a substrate on which a buffer layer is formed.

In step 2), a first material layer 10 and a second material layer 20 that are stacked are formed on the substrate 11 on which the source 15 and the drain 16 are formed.

The manufacturing method of the first material layer 10 and the second material layer 20 may refer to the step 4) in the manufacturing method of the bottom-gate thin film transistor.

In step 3), the first material layer 10 and the second material layer 20 are heated, so that the second material layer 20 induces the first material layer 10 to form crystals 30 of metal oxide semiconductor at least on a surface proximate to the second material layer 20 at a preset temperature. The preset temperature is greater than or equal to 200° C. and less than or equal to 420° C.

This step may refer to the step 5) in the manufacturing method of the bottom-gate thin film transistor.

The difference is that in a case where the second material layer 20 is formed above the first material layer 10 and the second material layer 20 is not removed, the second material layer 20 is used as the gate insulating layer 14 or a part of the gate insulating layer 14; alternatively, the second material layer 20 has the same pattern as the channel region 121 and is located between the gate insulation layer 14 and the first material layer 10.

In step 4), the gate insulating layer 14 is formed on the substrate 11 on which the semiconductor layer 12 is formed.

Here, only a case that the second material layer 20 is removed from the structure shown in (IV) in step 3) is shown. In a case where the second material layer 20 in step 3) is formed above the first material layer 10, and the second material layer 20 is not removed, this step may be omitted.

In step 5), a gate 13 is formed on the substrate 11 on which the first insulating layer 14 is formed.

For example, a pattern of the gate 13 may be the same as the pattern of the channel region 121.

The above description introduces a case where the source 15 and the drain 16 are disposed on a side of the semiconductor layer 12 proximate to the substrate 11. In a case where the source 15 and the drain 16 are disposed on a side of the semiconductor layer 12 away from the substrate 11, steps 2) and 3) occur before step 1). In this case, considering an example where the source 15 and the drain 16 are formed on a side of the gate 13 away from the substrate 11, the second material layer 20 may also be formed above or below the first material layer 10. Moreover, in a case where the second material layer 20 is formed above the first material layer 10 and the second material layer 20 is not removed, as shown in FIG. 4B, the second material layer 20 may be a whole layer. In this case, the second material layer 20 may be used as the gate insulating layer 14, and the second material layer 20 may be provided with via holes therein at positions corresponding to the source region 122 and the drain region 123, so as to achieve contact between the source 15 and the source region 122 and contact between the drain 16 and the drain region 123. Alternatively, as shown in FIG. 4C, the second material layer 20 has the same pattern as the channel region. In this case, via holes may only be formed in the interlayer insulating layer to achieve the contact between the source 15 and the source region 122 and the contact between the drain 16 and the drain region 123. In some other embodiments, as shown in FIG. 4D, the second material layer 20 is formed below the first material layer 10. In this case, the second material layer 20 may have the same pattern as the semiconductor layer 12, and via holes may also be formed in the interlayer insulating layer to achieve the contact between the source 15 and the source region 122 and the contact between the drain 16 and the drain region 123.

Some embodiments of the present disclosure provide an oxide semiconductor layer. The oxide semiconductor layer is obtained by making a metal induced layer in contact with an oxide semiconductor, and performing annealing at a temperature ranging from 200° C. to 420° C. to cause the oxide semiconductor and the metal induced layer to crystallize or partially crystallize at an interface between the oxide semiconductor and the metal induced layer.

The metal induced layer is the above first material layer, and the oxide semiconductor is the above second material layer. Performing annealing at the temperature ranging from 200° C. to 420° C. to cause the oxide semiconductor and the metal induced layer to crystallize or partially crystallize at the interface between the oxide semiconductor and the metal induced layer refers to heating at the temperature ranging from 200° C. to 420° C. to cause the oxide semiconductor to generate crystals of metal oxide semiconductor at least at the interface of the oxide semiconductor in contact with the metal induced layer.

In the oxide semiconductor layer provided by the present disclosure, the metal induced layer is utilized to be in contact with the oxide semiconductor to induce the oxide semiconductor and the metal induced layer to crystallize at the interface of the oxide semiconductor in contact with the metal induced layer at a relatively low temperature, so that the crystallization interface may be obtained. Compared with a case that the metal oxide semiconductor material of the oxide semiconductor layer is the amorphous oxide, the structural defects at the crystallization interface may be reduced, the density of the oxide semiconductor layer may be improved, and the intrinsic defects may be reduced. As a result, the carrier mobility and bias stability at the crystallization interface may be improved greatly.

Some embodiments of the present disclosure provide a semiconductor device. The semiconductor device includes the above oxide semiconductor layer.

The semiconductor device provided by the embodiments of the present disclosure has the same technical effects as the above oxide semiconductor layer, and details are not repeated here.

In some embodiments, the semiconductor device may include an integrated circuit, a photodetector, a semiconductor light-emitting diode, a semiconductor laser, a photocell, and the like.

Based on the above specific implementations, in order to objectively evaluate technical effects of the technical solutions provided in the present disclosure, the following will provide detailed and exemplary description of the technical solutions provided in the present disclosure through comparative examples and experimental examples.

### Comparative Example 1

A manufacturing method for the thin film transistor in Comparative Example 1 is as follows.

In step (1), a p-type heavily doped silicon with 300 μm is selected as the bottom gate (i.e., the gate 13) and the substrate 11, and a layer of SiO₂ with a thickness of 100 nm is grown as the gate insulating layer 14.

In step (2), an ITO film is deposited on the gate insulating layer 14 by magnetron sputtering to be as the source 15 and drain 16. The thickness is 50 nm, and the magnetron sputtering deposition parameters are as follows: direct current (DC) power 60 W, argon flow 30 sccm, oxygen flow 1 sccm, and working pressure 0.18 Pa.

In step (3), an ITZO (In:Sn:Zn=2:4:4, i.e., a ratio of the numbers of atoms of In, Sn and Zn is 2:4:4) film is deposited on the ITO by magnetron sputtering to be as the semiconductor layer 12. The thickness is 30 nm, and the magnetron sputtering deposition parameters are as follows: radio frequency (RF) power 100 W, argon flow 10 sccm, oxygen flow 10 sccm, and working pressure 0.2 Pa. The width and length of the channel are 800 μm and 400 μm respectively, and a 244 TFT control sample without Al inducing is obtained.

In step (4), in an air atmosphere, annealing is performed at 400° C. for 1 hour (i.e. heat treatment for 1 h) to obtain the 244 thin film transistor (i.e., 244 TFT).

### Experimental Example 1

Steps (1), (2) and (3) of a manufacturing method for the thin film transistor in Experimental Example 1 are substantially the same as the steps (1), (2) and (3) in Comparative Example 1, and details are not repeated here.

The difference is that before the step (4), Experimental Example 1 further includes the following steps.

Al with a thickness of 15 nm is deposited at a center of the ITZO channel through a mask to be as the second material layer 20. A dimension of Al in a direction of the width of the channel is 800 μm, and a dimension of Al in a direction of the length of the channel is 200 μm.

Moreover, substantially the same step as the above step (4) (i.e., in an air atmosphere, annealing at 400° C. for 1 hour) is used to obtain an Al/244 thin film transistor (i.e., Al/244 TFT).

In addition, after obtaining the Al/244 thin film transistor, Experimental Example 1 further includes the following step.

The second material layer 20 (i.e., the Al layer) is etched away by using 0.1 M NaOH. The etching time is 3 minutes. The etched Al/244 thin film transistor is then cleaned with deionized water, and the etched Al/244 thin film transistor is recorded as an Al/244-E thin film transistor (i.e., Al/244-E TFT).

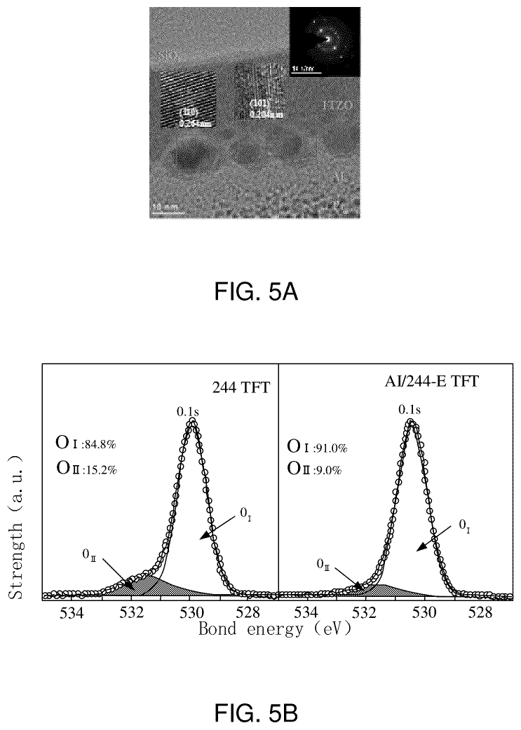

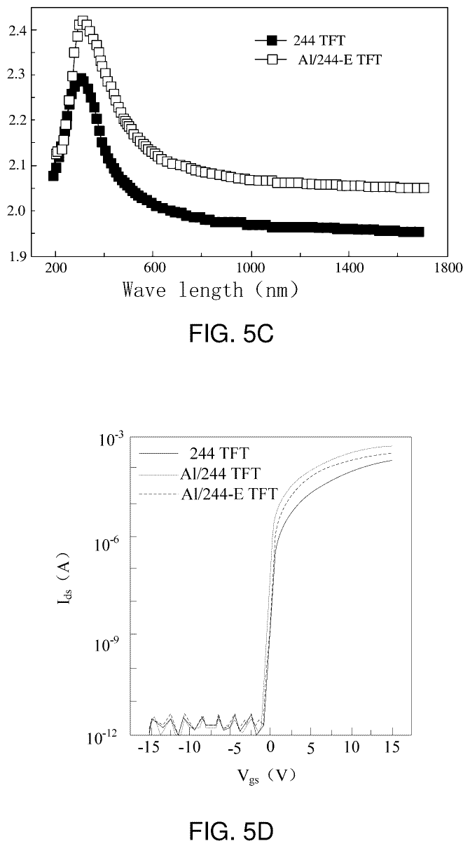

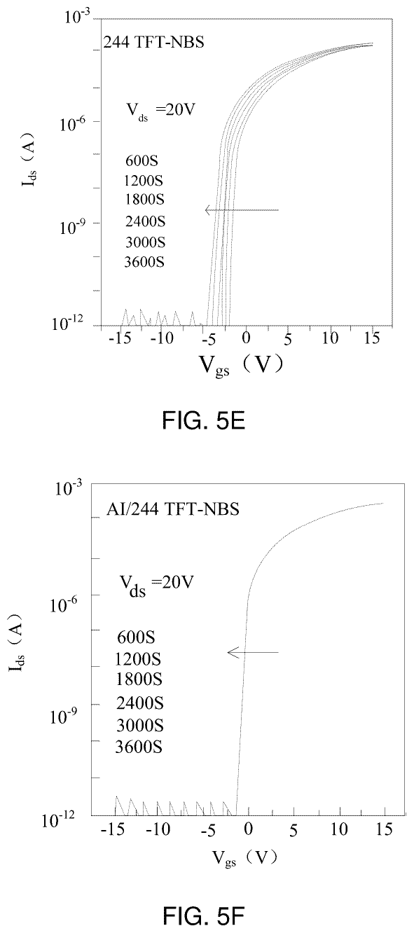

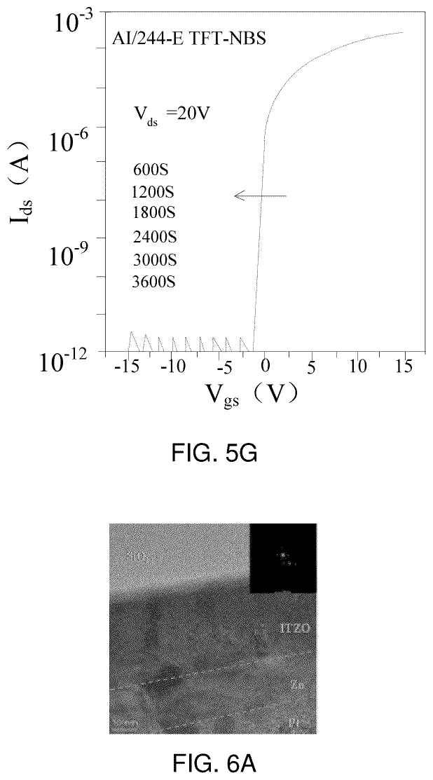

The thin film transistors obtained in Experimental Example 1 and Comparative Example 1 are observed by a transmission electron microscope, and a transmission electron microscope (TEM) image and an electron diffraction pattern of the semiconductor layer 12 of the Al/244 TFT shown in FIG. 5A are obtained. It can be seen that spherical crystals are generated at an interface of ITZO proximate to the Al layer. The thickness of the crystals 30 is in a range of 5 nm to 15 nm, and the corresponding electron diffraction pattern shows generation of ZnSnO₃ crystals.

The relative content of oxygen vacancies at the interface of ITZO proximate to the Al layer is tested by using an x-ray photoelectron spectrometer. As shown in FIG. 5B, the oxygen vacancies, i.e., an area (approximately 9%) of an integral region shown by O_{II}, in Experimental Example 1 are significantly reduced compared with an area (approximately 15.2%) of an integral region shown by O_{II} in the semiconductor layer 12 of the 244 TFT. In addition, Or represents an integrated region of oxygen in metal-oxygen bonds (i.e., an integrated region of all oxygen atoms except for the oxygen vacancies). Moreover, as shown in FIG. 5C, it is found through ellipsometry measurement that a refractive index of the interface of ITZO proximate to the Al layer in Experimental Example 1 is significantly higher than a refractive index of a surface of ITZO in Comparative Example 1, which indicates that the former has a low porosity and a high density. All of these show that after the induction of Al, the order degree of microstructures of ITZO is significantly improved, and structural defects such as micropores and oxygen vacancies are significantly reduced.

Moreover, the transfer characteristic curves of the Al/244 TFT and the Al/244-E TFT in Experimental Example 1 and the 244 TFT in Comparative Example 1 are tested under the condition of the drain voltage of 10.1 V, as shown in FIG. 5D. In addition, Table 1 lists characteristic parameters of the 244 TFT in Comparative Example 1 and both the Al/244 TFT and the Al/244-E TFT in Experimental Example 1.

TABLE 1

| | Vₜₕ | SS | μ_{FE} | Iₒₙ/I_{off} | ΔVₜₕ |
|---|---|---|---|---|---|
| sample | (V) | (V/dec) | (cm²/Vs) | (10⁷) | (V) |
| 244 | −0.21 | 0.19 | 19.1 | 7.6 | −2.08 |
| Al/244 | −0.21 | 0.18 | 53.2 | 24.9 | −0.24 |
| Al/244-E | −0.19 | 0.21 | 51.3 | 18.8 | −0.32 |
| Zn/244 | −0.24 | 0.19 | 52.8 | 22.7 | −0.97 |

It can be concluded in combination with Table 1 and FIG. 5D that, the thin film transistor in Experimental Example 1 before etching the aluminum layer (i.e., the second material layer 20) has a relatively high field effect mobility (FE) of 53.2 cm²/Vs, a relatively low subthreshold swing (SS) of 0.18 V/decade, a threshold voltage (Vₜₕ) of −0.21 V, and a relatively high on/off current ratio (Iₒₙ/I_{off}) of 2.49×10⁸ A. These parameters are all improved compared with those of the thin film transistor in Comparative Example 1. The thin film transistor in Experimental Example 1 after etching the aluminum layer has a field effect mobility (μ_{FE}) of 51.3 cm²/Vs, a relatively low subthreshold swing (SS) of 0.21 V/decade, a threshold voltage (Vₜₕ) of −0.19 V, and a relatively high on/off current ratio (Iₒₙ/I_{off}) of 1.88×10⁸ A. These parameters have little change compared with the parameters before etching, which indicates that the performance of the device can be substantially maintained after etching. In the negative bias stability (NBS, −20 V, 3600 s) test, in combination with Table 1 and FIGS. 5E, 5F and 5G, compared with 244 TFT (ΔVₜₕ=−2.08 V), Al/244 TFT exhibits a rather stable behavior (ΔVₜₕ=−0.24 V). In a case where the Al layer is etched away, ΔVₜₕ may still be maintained at a low level of about −0.32 V. The above description (NBS, −20 V, 3600 s) means that the test condition of the negative bias stability is as follows: the gate bias of −20 V and the time of 3600 s. FIGS. 5E, 5F and 5G respectively show comparison diagrams of transfer characteristic curves of 244 TFT, Al/244 TFT and Al/244-E TFT every 600 s from 600 s to 3600 s under the condition of the gate bias of −20 V, where arrows show drift directions of the threshold voltages of 244 TFT, Al/244 TFT and Al/244-E TFT as the test time goes. It can be seen from FIGS. 5E, 5F and 5G that as the test time goes from 600 s to 3600 s, the 244 TFT shows a large negative drift in the threshold voltage, while the Al/244 TFT and the Al/244-E TFT show no significant negative drift in threshold voltage.

### Experimental Example 2

The manufacturing method of the thin film transistor in Experimental Example 2 is substantially the same as that in Experimental Example 1. The difference is that the second material layer 20 is replaced with a metal Zn, and a Zn/244 thin film transistor (i.e., Zn/244 TFT) is obtained.

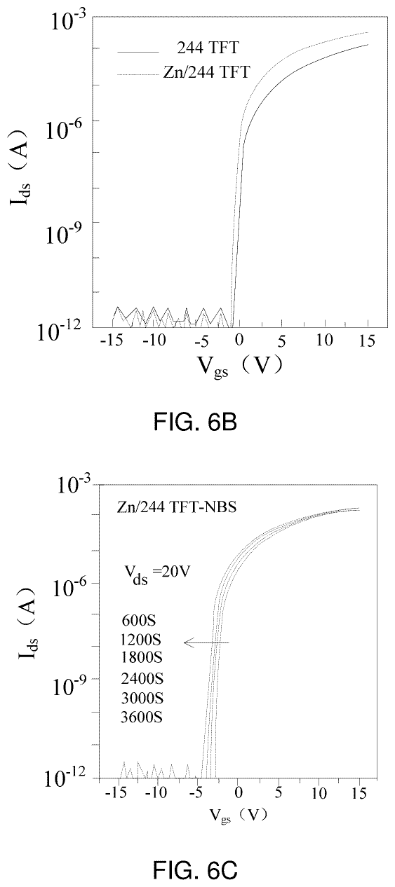

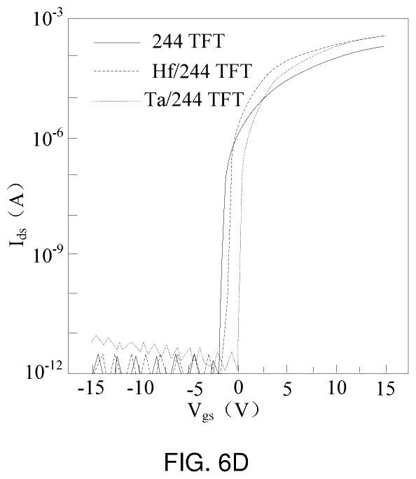

The thin film transistor is observed by a transmission electron microscope to obtain an TEM image and an electron diffraction pattern of the semiconductor layer 12 of the Zn/244 TFT shown in FIG. 6A. It can be seen that the entire ITZO film completely crystallize after Zn-induced crystallization. The electron diffraction pattern shows formation of ZnSnO₃ crystals. These indicate that after the induction action of Zn, ordering of microstructures of ITZO is significantly improved.

The transfer characteristic curve of the Zn/244 TFT in Experimental Example 2 is tested under the condition of the drain voltage of 10.1 V, as shown in FIG. 6B. In addition, Table 1 lists characteristic parameters of the Zn/244 TFT.

In combination with Table 1 and FIG. 6B, the Zn/244 TFT has a relatively high field effect mobility (μ_{FE}) of 52.8 cm²/Vs, a relatively low subthreshold swing (SS) of 0.19 V/decade, a threshold voltage (Vₜₕ) of −0.24 V, and a relatively high on/off current ratio (Iₒₙ/I_{off}) of 2.27×10⁸ A. These parameters are all improved compared with those of the 244 TFT. In combination with FIG. 6C and Table 1, in the negative bias stability test (the test condition of NBS is as follows: the gate bias of −20 V and the time of 3600 s), compared with the 244 TFT (ΔVₜₕ=−2.08 V), the Zn/244 TFT shows relatively stable behavior (ΔVₜₕ=−0.97 V). FIG. 6C shows a comparison diagram of transfer characteristic curves corresponding to the Zn/244 TFT every 600 s from 600 s to 3600 s under the condition of the gate bias of −20 V, where the arrow shows a drift direction of the threshold voltage of the Zn/244 TFT as the test time goes. It can be seen from FIG. 6C that as the test time goes from 600 s to 3600 s, the threshold voltage of the Zn/244 TFT has a certain degree of negative drift, but the drift amount is relatively small compared to the 244 TFT.

### Experimental Example 3

The manufacturing method of the thin film transistor in Experimental Example 3 is substantially the same as that in Experimental Example 1. The difference is that the second material layer 20 in Experimental Example 3 is replaced with a metal Ta, and a Ta/244 thin film transistor (i.e., Ta/244 TFT) is obtained.

### Experimental Example 4

The manufacturing method of the thin film transistor in Experimental Example 4 is substantially the same as that in Experimental Example 1. The difference is that the second material layer 20 in Experimental Example 4 is replaced with a metal Hf, and a Hf/244 thin film transistor (i.e., Hf/244 TFT) is obtained.

The transfer characteristic curves of the thin film transistors in Experimental Example 3 and Experimental Example 4 are tested under the condition of the drain voltage of 10.1 V, as shown in FIG. 6D. It can be seen that the threshold voltages in the transfer characteristic curves of the two are both close to 0 V. In a turn-off state of the channel, the leakage current is around 10-12 A, which is at a relatively low level. In a turn-on state of the channel, the channel current increases rapidly, and rise to a relatively high level. The field effect mobility (μ_{FE}) of the Ta/244 TFT is 53.3 cm²/Vs, and the field effect mobility (FE) of the Hf/244 TFT is 54.9 cm²/Vs.

### Experimental Example 5

The manufacturing method of the thin film transistor in Experimental Example 5 is substantially the same as that in Experimental Example 1. The difference is that the second material layer 20 in Experimental Example 5 is replaced with ZnO, and a ZnO/244 thin film transistor (i.e., ZnO/244 TFT) is obtained.

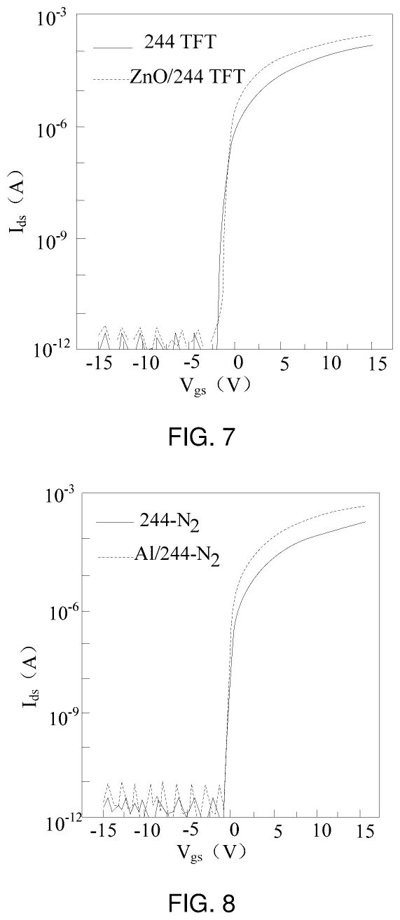

The transfer characteristic curve of the thin film transistor in Experimental Example 5 is tested under the condition of the drain voltage of 10.1 V, as shown in FIG. 7. It can be seen that the threshold voltage in the transfer characteristic curve is close to 0 V. In a turn-off state of the channel, the leakage current is around 10-12 A, which is at a relatively low level. In a turn-on state of the channel, the channel current increases rapidly, and rise to a relatively high level. The field effect mobility (μ_{FE}) of the ZnO/244 TFT may reach 41.8 cm²/Vs.

### Comparative Example 2

The manufacturing method of the thin film transistor in Comparative Example 2 is substantially the same as that in Comparative Example 1. The difference is that the step (4) is performed in a nitrogen atmosphere, and a 244-N₂ thin film transistor (i.e., 244-N₂ TFT) is obtained.

### Experimental Example 6

The manufacturing method of the thin film transistor in Experimental Example 6 is substantially the same as that in Experimental Example 1. The difference is that the step (4) is performed in a nitrogen atmosphere, and an Al/244-N₂ thin film transistor (i.e., Al/244-N₂ TFT) is obtained.

The transfer characteristic curves of the Al/244-N₂ TFT in Experimental Example 6 and the 244-N₂ TFT in Comparative Example 2 are tested under the condition of the drain voltage of 10.1 V, as shown in FIG. 8. It can be seen that the threshold voltages in the transfer characteristic curves are close to 0 V. In a turn-off state of the channel, the leakage current is around 10-12 A, which is at a relatively low level. In a turn-on state of the channel, the channel current increases rapidly, and rise to a relatively high level. The field effect mobility (μ_{FE}) of the 244-N₂ TFT is 17.6 cm²/Vs, and the field effect mobility (μ_{FE}) of the Al/244-N₂ TFT is as high as 49.4 cm²/Vs.

### Comparative Example 3

The manufacturing method of the thin film transistor in Comparative Example 3 is substantially the same as that in Comparative Example 1. The difference is that the first material layer in Comparative Example 3 is replaced with ITZO (In:Sn:Zn=4:2:4, i.e., a ratio of the numbers of atoms of In, Sn and Zn is 4:2:4), and a 424 thin film transistor (i.e., 424 TFT) is obtained.

### Experimental Example 7

The manufacturing method of the thin film transistor in Experimental Example 7 is substantially the same as that in Experimental Example 1. The difference is that the first material layer in Experimental Example 7 is replaced with ITZO (In:Sn:Zn=4:2:4, i.e., a ratio of the numbers of atoms of In, Sn and Zn is 4:2:4), and an Al/424 thin film transistor (i.e., Al/424 TFT) is obtained.

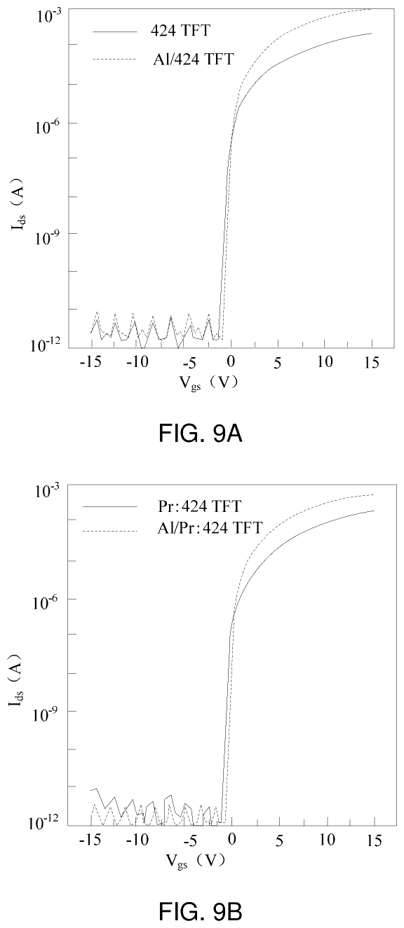

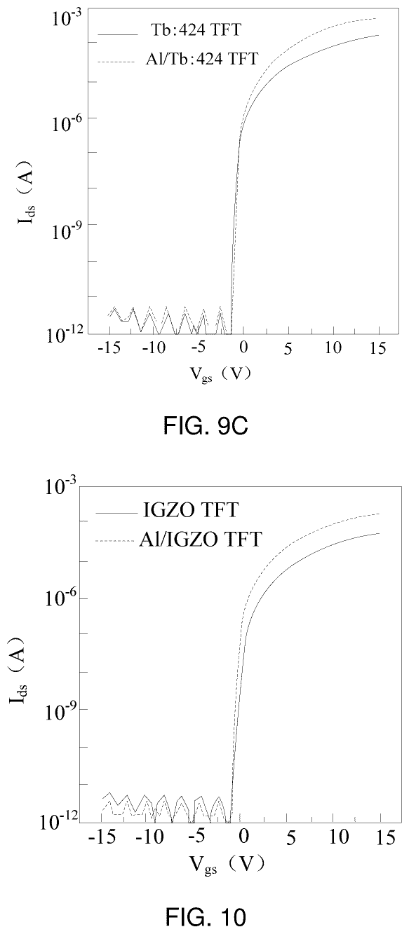

The transfer characteristic curves of the Al/424 TFT in Experimental Example 7 and the 424 TFT in Comparative Example 2 are tested under the condition of the drain voltage of 10.1 V, as shown in FIG. 9A. It can be seen that the threshold voltages in the transfer characteristic curves are close to 0 V. In a turn-off state of the channel, the leakage current is around 10-12 A, which is at a relatively low level. In a turn-on state of the channel, the channel current increases rapidly, and rise to a relatively high level. The field effect mobility (μ_{FE}) of the Al/424 TFT is relatively high of 163.5 cm²/Vs, and the field effect mobility (μ_{FE}) of the 424 TFT is only 31.5 cm²/Vs.

### Comparative Example 4

The manufacturing method of the thin film transistor in Comparative Example 4 is substantially the same as that in Comparative Example 3. The difference is that the first material layer 10 in Comparative Example 4 is replaced with Pr-doped ITZO (In:Sn:Zn=4:2:4, i.e., a ratio of the numbers of atoms of In, Sn and Zn is 4:2:4, and a doping concentration of Pr is 2 at %), and a Pr:424 thin film transistor (i.e., Pr:424 TFT) is obtained.

### Experimental Example 8

The manufacturing method of the thin film transistor in Experimental Example 8 is substantially the same as that in Experimental Example 7. The difference is that the first material layer 10 in Experimental Example 8 is replaced with Pr-doped ITZO (In:Sn:Zn=4:2:4, i.e., a ratio of the numbers of atoms of In, Sn and Zn is 4:2:4, and a doping concentration of Pr is 2 at %), and an Al/Pr:424 thin film transistor (i.e., Al/Pr:424 TFT) is obtained.

The transfer characteristic curves of the Al/Pr:424 TFT in Experimental Example 8 and the Pr:424 TFT in Comparative Example 4 are tested under the condition of the drain voltage of 10.1 V, as shown in FIG. 9B. It can be seen that the threshold voltages in the transfer characteristic curves are close to 0V. In a turn-off state of the channel, the leakage current is around 10-12 A, which is at a relatively low level. In a turn-on state of the channel, the channel current increases rapidly, and rise to a relatively high level. The field effect mobility (μ_{FE}) of the Pr:424 TFT is 38.4 cm²/Vs, and the field effect mobility (μ_{FE}) of the Al/Pr:424 TFT is as high as 81.0 cm²/Vs.

### Comparative Example 5

The manufacturing method of the thin film transistor in Comparative Example 5 is substantially the same as that in Comparative Example 4. The difference is that the first material layer 10 in Comparative Example 5 is replaced with Tb-doped ITZO (In:Sn:Zn=4:2:4, i.e., a ratio of the numbers of atoms of In, Sn and Zn is 4:2:4, and a doping concentration of Tb is 2 at %), and a Tb:424 thin film transistor (i.e., Tb:424 TFT) is obtained.

### Experimental Example 9

The manufacturing method of the thin film transistor in Experimental Example 9 is substantially the same as that in Experimental Example 8. The difference is that the first material layer 10 in Experimental Example 9 is replaced with Tb-doped ITZO (In:Sn:Zn=4:2:4, i.e., a ratio of the numbers of atoms of In, Sn and Zn is 4:2:4, and a doping concentration of Tb is 2 at %), and an Al/Tb:424 thin film transistor (i.e., Al/Tb:424 TFT) is obtained.

The transfer characteristic curves of the Al/Tb:424 TFT in Experimental Example 9 and the Tb:424 TFT in Comparative Example 5 are tested under the condition of the drain voltage of 10.1 V, as shown in FIG. 9C. It can be seen that the threshold voltages in the transfer characteristic curves are close to 0V. In a turn-off state of the channel, the leakage current is around 10-12 A, which is at a relatively low level. In a turn-on state of the channel, the channel current increases rapidly, and rise to a relatively high level. The field effect mobility (FE) of the Tb:424 TFT is 31.3 cm²/Vs, and the field effect mobility (μ_{FE}) of the Al/Tb:424 TFT is as high as 79.6 cm²/Vs.

### Comparative Example 6

The manufacturing method of the thin film transistor in Comparative Example 6 is substantially the same as that in Comparative Example 5. The difference is that the first material layer 10 in Comparative Example 6 is replaced with IGZO (In:Ga:Zn=1:1:1, i.e., a ratio of the numbers of atoms of In, Ga and Zn is 1:1:1), and an IGZO thin film transistor (i.e., IGZO TFT) is obtained.

### Experimental Example 10

The manufacturing method of the thin film transistor in Experimental Example 10 is substantially the same as that in Experimental Example 9. The difference is that the first material layer 10 in Experimental Example 10 is replaced within IGZO (In:Ga:Zn=1:1:1, i.e., a ratio of the numbers of atoms of In, Ga and Zn is 1:1:1), and an Al/IGZO thin film transistor (i.e., Al/IGZO TFT) is obtained.

The transfer characteristic curves of the Al/IGZO TFT in Experimental Example 10 and the IGZO TFT in Comparative Example 6 are tested under the condition of the drain voltage of 10.1 V, as shown in FIG. 10. It can be seen that the threshold voltages in the transfer characteristic curves are close to 0V. In a turn-off state of the channel, the leakage current is around 10-12 A, which is at a relatively low level. In a turn-on state of the channel, the channel current increases rapidly, and rise to a relatively high level. The field effect mobility (μ_{FE}) of the IGZO TFT is 10.7 cm²/Vs, and the field effect mobility (μ_{FE}) of the Al/IGZO TFT may reach 30.3 cm²/Vs.

To sum up, the second material layer 20 is introduced and induction is performed at a relatively low temperature, so that the second material layer 20 induces the first material layer 10 to generate the crystals 30 of metal oxide semiconductor. Compared with a case that the metal oxide semiconductor material in the semiconductor layer 12 is the amorphous oxide, the density of the semiconductor layer 12 may be improved, and the structural defects such as voids and micropores in the semiconductor layer may be reduced, thereby improving the carrier mobility (i.e., electron mobility) of the semiconductor layer 12. In addition, the ordering of microstructures (e.g., the atomic structures of metal oxide semiconductor materials) may increase overlap of electron clouds between atoms, reduce the scattering effect of the electrons during transportation, and improve the electron mobility. Moreover, the improvement of the microstructures may further reduce oxygen vacancies, thereby improving the bias stability. In addition, by controlling the heating temperature during induction to be at a relatively low temperature, the flexible substrate may be used in the manufacture, thereby meeting the future application needs for flexible panels.

The foregoing descriptions are merely specific implementations of the present disclosure, but the protection scope of the present disclosure is not limited thereto. Any person skilled in the art could conceive of changes or replacements within the technical scope of the present disclosure, which shall all be included in the protection scope of the present disclosure. Therefore, the protection scope of the present disclosure shall be subject to the protection scope of the claims.

1. A thin film transistor, comprising:
a substrate; and
a semiconductor layer disposed on the substrate, the semiconductor layer including a first surface proximate to the substrate and a second surface away from the substrate, and a material of the semiconductor layer being a metal oxide semiconductor material; wherein
the semiconductor layer has a channel region, and the semiconductor layer is provided with crystals of metal oxide semiconductor at least in the channel region and proximate to one of the first surface and the second surface.

2. The thin film transistor according to claim 1, wherein
a thickness of the crystals in the semiconductor layer is greater than or equal to ¼ of a thickness of the semiconductor layer and less than or equal to the thickness of the semiconductor layer.

3. The thin film transistor according to claim 1, wherein
a dimension of a distribution range of the crystals in a direction of a length of a channel of the semiconductor layer is greater than or equal to ½ of the length of the channel of the semiconductor layer and is less than or equal to the length of the channel of the semiconductor layer.

4. The thin film transistor according to claim 1, further comprising a metal oxide layer, wherein the metal oxide layer covers at least a middle of the channel region in a direction of a length of a channel, and a dimension of the metal oxide layer in the direction of the length of the channel is greater than or equal to ½ of the length of the channel; and the metal oxide layer is in contact with the semiconductor layer.

5. The thin film transistor according to claim 4, further comprising a gate insulating layer, wherein the metal oxide layer is disposed between the gate insulating layer and the semiconductor layer.

6. The thin film transistor according to claim 4, wherein
in the semiconductor layer, a distribution density of the crystals increases in a direction approaching the metal oxide layer.

7. The thin film transistor according to claim 1, wherein
the material of the semiconductor layer is selected from any of indium zinc tin oxide and indium gallium zinc oxide; and the indium zinc tin oxide and the indium gallium zinc oxide are doped or not doped with rare earth elements.

8. The thin film transistor according to claim 7, wherein
in a case where the indium zinc tin oxide and the indium gallium zinc oxide are doped with a rare earth element, the rare earth element is praseodymium (Pr) or terbium (Tb).

9. The thin film transistor according to claim 7, wherein
in a case where the indium zinc tin oxide is selected as the material of the semiconductor layer, a ratio of a number of atoms of indium (In), a number of atoms of tin (Sn) and a number of atoms of zinc (Zn) in the indium zinc tin oxide is 4:2:4, or a ratio of the number of atoms of In, the number of atoms of Sn and the number of atoms of Zn in the indium zinc tin oxide is 2:4:4; and
in a case where the indium gallium zinc oxide is selected as the material of the semiconductor layer, a ratio of a number of atoms of In, a number of atoms of gallium (Ga) and a number of atoms of Zn in the indium gallium zinc oxide is 1:1:1.

10. The thin film transistor according to claim 8, wherein
a doping concentration of the rare earth element is 2 at %.

11. The thin film transistor according to claim 1, wherein
an oxygen vacancy concentration of the semiconductor layer is less than or equal to 10%.

12. A display panel, comprising the thin film transistor according to claim 1.

13. A display device, comprising the display panel according to claim 12.

14. A manufacturing method for a thin film transistor, wherein the thin film transistor includes a substrate and a semiconductor layer, and the semiconductor layer includes a channel region;
the manufacturing method comprises:
forming a first material layer and a second material layer that are stacked on the substrate, the first material layer being in contact with the second material layer, wherein the first material layer is a whole layer or the first material layer has a same pattern with the semiconductor layer; an orthographic projection of the second material layer on the substrate at least covers a middle of the first material layer corresponding to the channel region in a direction of a length of a channel, and a dimension of the orthographic projection of the second material layer on the substrate in the direction of the length of the channel is greater than or equal to ½ of the length of the channel; a material of the first material layer is a metal oxide semiconductor material, and a material of the second material layer is a metal or a metal oxide;
heating the first material layer and the second material layer to cause the second material layer to induce the first material layer to form crystals of metal oxide semiconductor at least on a surface proximate to the second material layer at a preset temperature, the preset temperature being greater than or equal to 200° C. and less than or equal to 420° C.; and
in a case where the first material layer is the whole layer, patterning the first material layer to form the semiconductor layer after the induction is completed.

15. The manufacturing method for the thin film transistor according to claim 14, wherein
the preset temperature is less than or equal to 400° C.; and/or
a heating time is in a range of 0.5 h to 4 h.

16. (canceled)

17. The manufacturing method for the thin film transistor according to claim 14, wherein
the metal is selected from one of or alloys consisting of aluminum, zinc, tin, tantalum, hafnium, zirconium and titanium; and/or
the metal oxide at least includes one or a combination of aluminum oxide, zinc oxide, tin oxide, tantalum oxide, hafnium oxide, zirconium oxide and titanium oxide.

18. (canceled)

19. The manufacturing method for the thin film transistor according to claim 14, wherein
a heating atmosphere is an oxygen-containing atmosphere, an inert atmosphere or a vacuum atmosphere.

20. The manufacturing method for the thin film transistor according to claim 1, wherein
forming the first material layer and the second material layer that are stacked on the substrate, includes:
sequentially forming the first material layer and the second material layer on the substrate; or
sequentially forming the second material layer and the first material layer on the substrate.

21. The manufacturing method for the thin film transistor according to claim 20, wherein in a case where the first material layer and the second material layer are sequentially formed on the substrate, the manufacturing method further comprises: removing the second material layer after induction is completed.

22. An oxide semiconductor layer, the oxide semiconductor layer is obtained by making a metal induced layer in contact with an oxide semiconductor, and performing annealing at a temperature ranging from 200° C. to 420° C. to cause the oxide semiconductor and the metal induced layer to crystallize or partially crystallize at an interface between the oxide semiconductor and the metal induced layer.
